(19) United States
(12) Patent Application Publication
(10) Pub. No.: US 2013/0043555 A1
(43) Pub. Date: Feb. 21, 2013

(54) ELECTROSTATIC DISCHARGE (ESD) PROTECTION ELEMENT AND ESD CIRCUIT THEREOF

(71) Applicant: Ching-Ling Tsai, Tainan City (TW)

(72) Inventor: Ching-Ling Tsai, Tainan City (TW)

(73) Assignee: HIMAX TECHNOLOGIES LIMITED, Tainan City (TW)

(21) Appl. No.: 13/212,949

(22) Filed: Aug. 18, 2011

(51) Int. Cl. H01L 29/06; H01L 29/86

(52) U.S. Cl. 257/516; 257/510; 257/E29.002; 257/E29.325

(57) ABSTRACT

An ESD protection circuit connected between an I/O pad and an internal circuit is disclosed. The ESD protection circuit includes a P type ESD protection element which has a first P type doped region and a first N type doped region. The covered shape of the first P type doped region is a polygon having at least eight edges, wherein the polygon is bilateral symmetry, and the first N type doped region is disposed to encompass said first P type doped region. During an ESD event, the first P type doped region of the P type ESD protection element receives an ESD current and uniformly drains it away.

### BACKGROUND OF THE INVENTION

1. Field of the Invention

The present invention generally relates to an electrostatic discharge (ESD) protection element, and more particularly to an electrostatic discharge (ESD) protection element for an electrostatic discharge protection circuit.

2. Description of Related Art

In integrated circuits (IC) design, electrostatic discharge (ESD) is a significant problem, especially for devices with high pin counts and circuit speeds. In order to avoid a high-energy electrical discharge current, produced at the input/output nodes of an IC device, entering into the IC device to destroy its internal circuit, an ESD protection circuit is usually configured between the internal circuit and the input/output nodes of the IC device. When excessive transient voltages or currents occur, the ESD protection circuit can respond in time and direct the excessive transient voltages or currents into the power rails to avoid those voltages or currents from flowing to the core circuits.

FIG. 1 illustrates a traditional electrostatic discharge (ESD) protection circuit. As shown in FIG. 1, the ESD protection circuit 13 is connected between an I/O pad 11 and an internal circuit 15 for protecting the internal circuit 15 from ESD damage. The ESD protection circuit 13 comprises two series-connected and reverse biased diodes 131, 133, one formed between the power source Vs and the I/O pad 11, and the other formed between the ground and the I/O pad 11. The reverse biased diode 131 (or 133) turns into break down mode when the voltage on the I/O pad 11 exceeds the break down voltage of the reverse biased diode 131 (or 133), so as to bypass and shunt the current quickly.

FIGS. 2A and 2B illustrate the traditional diodes for the ESD protection circuit 13. Due to the square and rectangular shapes of the diodes 131, 133, when draining the ESD current, the charges may often be accumulated at four corners of the diodes 131, 133 to occur partial damage, and result in permanent failure of the diodes 131, 133. In order to overcome the above issue, it usually increases the junction area of the diodes 131, 133 to pass through larger transient voltages or currents. However, the more the junction area of the diodes 131, 133 requires, the bigger the size of the IC device is, and the manufacturing cost may be raised.

There remains an unsatisfied need for more sensitive and higher HBM (Human Body Mode) ESD ability ESD circuits. Therefore, a need has arisen to propose a novel ESD protection element layout and circuit which have higher HBM ESD ability to bypass transient voltages or currents without extensive overhead circuitry and with an efficient use of IC space.

### SUMMARY OF THE INVENTION

In view of the foregoing, it is an object of the present invention to provide an ESD protection element and circuit thereof which have higher HBM (Human Body Mode) ESD ability to bypass transient voltages or currents without extensive overhead, circuitry and with an efficient use of IC space.

According to one embodiment, an ESD protection element for draining an ESD current of an ESD protection circuit is disclosed. The ESD protection element includes a first conductivity type doped region, a second conductivity type doped region and an isolation structure. The covered shape of the first conductivity type doped region is a polygon having for instance (e.g., preferably) at least eight edges, wherein the polygon is bilateral symmetry, and the second conductivity type doped region is disposed to encompass said first conductivity type doped region. The isolation structure is disposed between the first conductivity type doped region and the second conductivity type doped region. During an ESD event, the first conductivity type doped region receives the ESD current and uniformly drains it away.

According to another embodiment, an ESD protection circuit connected between an I/O pad and an internal circuit is disclosed. The ESD protection circuit includes a P type ESD protection element which has a first P type doped region and a first N type doped region. The covered shape of the first P type doped region is a polygon having for instance (e.g., preferably) at least eight edges, wherein the polygon is bilateral symmetry, and the first N type doped region is disposed to encompass said first P type doped region. During an ESD event, the first P type doped region of the P type ESD protection element receives an ESD current and uniformly drains it away.

### BRIEF DESCRIPTION OF THE DRAWINGS

FIG. 1 illustrates a traditional electrostatic discharge (ESD) protection circuit;

FIGS. 2A and. 2B illustrate the traditional diodes for the ESD protection circuit;

FIG. 3 illustrates an electrostatic discharge (ESD) protection circuit according to one embodiment of the present invention; and

FIG. 4 illustrates an electrostatic discharge protection element for the ESD protection circuit according to one embodiment of the present invention.

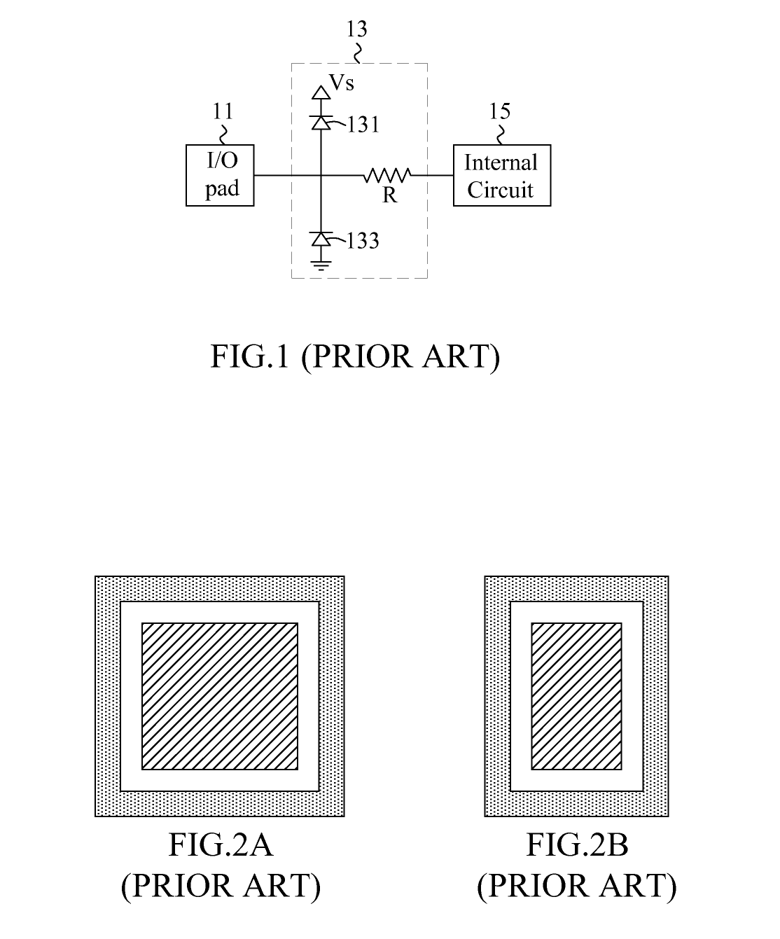

### DETAILED DESCRIPTION OF THE INVENTION

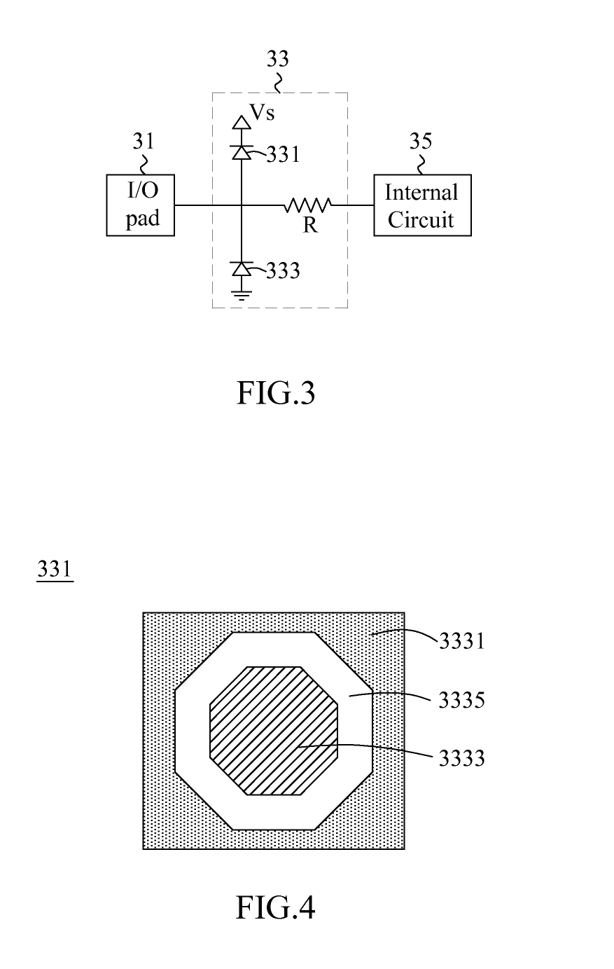

Firstly, FIG. 3 illustrates an electrostatic discharge (ESD) protection circuit 33 according to one embodiment of the present invention. As shown in FIG. 3, the ESD protection circuit 33 is connected between an I/O pad 31 and an internal circuit 35 for protecting the internal circuit 35 from ESD damage. The ESD protection circuit 33 includes a P type ESD protection element 331, an N type ESD protection element 333 and a resistor R. The P type ESD protection element 331 is connected between the I/O pad 31 and the power source Vs, and the N type ESD protection element 333 is connected between the I/O pad 31 and the ground. Wherein, the N type ESD protection element 333 is series-connected, to the P type ESD protection element 331, and the resistor R is connected between the I/O pad 31 and the internal circuit 35.

In one embodiment, the internal circuit 35 is a single chip, a timing controller or a driving circuit. The P type ESD protection element 331 is a P type diode, and the N type ESD protection element 333 is an N type diode. Referring to FIG. 4, taking the P type ESD protection element 331 for example, the diode layout has a first N type doped region 3331, a first P type doped region 3333 and an isolation structure 3335. The covered, shape of the first P type doped region 3333 is a polygon having for instance (e.g., preferably) at least eight edges, wherein the polygon is bilateral symmetry, and the first N type doped region 3331 is disposed to encompass said first P type doped region 3333. The isolation structure 3335 is disposed between the first N type doped region 3331 and the first P type doped region 3333. In one embodiment, the isolation structure 3335 comprises a shallow trench isolation (STI) layer, and its outer side line, connecting with the first N type doped region 3331, may be formed into a polygon or other multi-sided, oval, substantially circular or hybrid shape, but is not limited to such.

When user contacts the I/O pad 31 to generate an ESD current (an ESD event occurs), the first P type doped region 3333 of the P type ESD protection element 331 receives the ESD current and uniformly drains it away due to the polygon shape of the first P type doped region 3333.

Similarly, the internal of the N type ESD protection element 333 is an N type doped region (second N type doped region), and its covered shape is also a polygon having at least eight edges. When user contacts the I/O pad 31 to occur the ESD event, the N type doped region of the N type ESD protection element 333 receives the ESD current and uniformly drains it away due to the polygon shape of the N type doped region.

According to the above embodiment, the ESD protection circuit, provided in the present invention, changes the layout structure of the ESD protection element to enable to uniformly drain away transient voltages or currents from the I/O pad 31. Test and verify via Testkey, in the same area of the circuit, the HBM ESD ability of the polygon ESD protection diode has increased by 50 percent as compared with the traditional square ESD protection diode, which achieves decreased cost.

Although specific embodiments have been illustrated and described, it will be appreciated by those skilled in the art that various modifications may be made without departing from the scope of the present invention, which is intended to be limited solely by the appended claims.

1. An electrostatic discharge (ESD) protection element for draining an ESD current of an ESD protection circuit, comprising:
a first conductivity type doped region, wherein a covered shape of the first conductivity type doped region is a polygon having at least eight edges, wherein the polygon is bilateral symmetry;
a second conductivity type doped region disposed to encompass the first conductivity type doped region; and
an isolation structure disposed between the first conductivity type doped region and the second conductivity type doped region;
wherein the ESD protection circuit is connected between an I/O pad and a timing controller, and an ESD event occurs when contacting the I/O pad to generate the ESD current; and
wherein during the ESD event, the first conductivity type doped region receives the ESD current and uniformly drains it away.

2. The ESD protection element of claim 1, wherein the first conductivity type doped region is P type doped region, and the second conductivity type doped region is N type doped region.

3. The ESD protection element of claim 1, wherein the first conductivity type doped region is N type doped region, and the second conductivity type doped region is P type doped region.

4. (canceled)

5. (canceled)

6. The ESD protection element of claim 1, wherein the isolation structure comprises a shallow trench isolation (STI) layer, and an outer side line, connecting with the second conductivity type doped region, of the isolation structure comprises a polygonal or substantially circular shape.

7. An electrostatic discharge (ESD) protection circuit connected between an I/O pad and a timing controller, comprising:
a P type ESD protection element connected between the I/O pad and a power source, comprising:
a first P type doped region, wherein a covered shape of the first P type doped region is a polygon having at least eight edges, wherein the polygon is bilateral symmetry; and
a first N type doped region disposed to encompass the first P type doped region;
wherein during an ESD event, the first P type doped region of the P type ESD protection element receives an ESD current and uniformly drains it away.

8. The ESD protection circuit of claim 7, further comprising:
an N type ESD protection element connected between the I/O pad and ground, wherein the N type ESD protection element is series-connected to the P type ESD protection element, comprising:
a second N type doped region, wherein a covered shape of the second N type doped region is the polygon; and
a second P type doped region disposed to encompass the second N type doped region; and
a resistor connected between the I/O pad and the timing controller;
wherein during an ESD event, the second N type doped region of the N type ESD protection element receives the ESD current and uniformly drains it away.

9. The ESD protection circuit of claim 8, wherein the P type ESD protection element further comprises an isolation structure which is disposed between the first P type doped region and the first N type doped region, and the N type ESD protection element further comprises the isolation structure which is disposed between the second N type doped region and the second P type doped region.

10. The ESD protection circuit of claim 9, wherein the isolation structure comprises a shallow trench isolation (STI) layer, and an outer side line, connecting with the first N type doped region or the second P type doped region, of the isolation structure is shaped into a polygon or substantially a circle.

11. The ESD protection circuit of claim 9, wherein the P type ESD protection element is P type diode, and the N type ESD protection element is N type diode.

12. The ESD protection circuit of claim 8, wherein the ESD event occurs when contacting the I/O pad to generate the ESD current.

13. (canceled)
